(19) United States
(12) Patent Application Publication
(10) Pub. No.: US 2009/0174991 A1
(43) Pub. Date: Jul. 9, 2009

(54) Generation Power Cable for Computers

(76) Inventor: Mohhamad Mahdavi, Louisville, KY (US)

Correspondence Address: ROBERT R. WATERS, ESQ.;WATERS LAW OFFICE, PLLC, 633 SEVENTH STREET, HUNTINGTON, WV, 25701, US

(21) Appl. No.: 11/969,898

(22) Filed: Jan. 5, 2008

(51) Int. Cl. H05K 7/00; G06F 3/048; H01R 11/00; B23P 19/00

(52) U.S. Cl. 361/679.02; 715/772; 439/502; 29/426.1

(57) ABSTRACT

A power cable for a computer has a main cable with two ends and each end terminates in a plug. One plug on the main cable is configured to connect to a power supply and the other plug on the main cable is configured to connect to a computer motherboard. Secondary cables terminate at one end in either the plug for the power supply or the plug for the motherboard. The secondary cables have plugs configured to connect to electrical devices that require power. The secondary cables may split into tertiary cables, and the plugs on the secondary and tertiary cables may be any of a variety found in computers.

### FIELD OF THE INVENTION

This invention relates generally to power cables in computers.

### BACKGROUND OF THE INVENTION

A very high percentage, if not all, of modern personal computers have an internal power supply located within the computer case of the personal computer. Frequently, when a personal computer ceases to function, it is because the power supply has failed. Anecdotal evidence as well as some studies indicate that the failure of a power supply is the most frequent reason for personal computer failure.

Presently, most internal power supplies for computers have a power cable hardwired into the internal sections of the power supply. This power cable has a main cable which runs to the mother hoard of the computer and this power cable also has several secondary power cables which have plugs to connect into the several drives typical in a computer. These drives include: the hard drive; disc drives; such as CD, 3½ inch discs, and DVD drives. Alternatively, the secondary cables may exit the power supply separate from the main cable. These most typical cable arrangements require that when a power supply fails, each power connection within the computer must be unplugged so that the failed power supply may be removed. When a new power supply is installed, each of these power connections must be accounted for and reconnected. This is a somewhat tedious and relatively labor intensive operation for the routine replacement of a failed power supply. Along with this wasteful use of labor, there is significant waste in disposing of a power supply having a power cable hardwired to it. For the above reasons, as well as others, there is a need for cable apparatus that does not require the disconnection of each power connection when a power supply is replaced.

### DESCRIPTION OF RELATED ART

U.S. Pat. No. 6,314,001 B1 by Chu claims a computer having an external power, supply with a plurality of power supplying outputs. Chu also claims a cable portion within the computer housing which extends outside the computer housing and a mating cable between that cable and the power supply. U.S. Pat. No. 7,133,293 B2 by Fiorentino et al discloses and claims a power supply with both a hardwired power cable and additional multiple power outlets for additional special power cables. Similarly, U.S. Pat. No. 7,187,544 B2 by Tsai discloses a computer power supply having a hardwired power cable along with multiple power outlets on the power supply for additional power cables. U.S. Published Application 2007/0167073 A1 by Tsai discloses a power supply having multiple power outlets for multiple power cables. U.S. Published Application 2006/0262492 A1 by Tsai discloses an adapter plate which may be fixed upon a power supply. The power supply has at least one multi-pin receptacle, and the adapter plate connects to this receptacle and provides multiple power outlets to accommodate multiple power cables.

### SUMMARY OF THE INVENTION

The embodiments of the present invention include in their construction, a first plug adapted and configured to plug into a power supply, a main cable connected to that first plug, a second plug attached to the other end of the main cable and adapted and configured to plug into the mother board of the computer, and at least one secondary power cable attached to the second plug. At least one secondary cable has at least one plug on it which is capable of attaching to an electrical device in the computer such as a drive. At least one secondary cable may have several power plugs along its length with each of these power plugs being wired in parallel so that each of the plugs is capable of providing power to an electrical device within the computer. The main cable and secondary cables are made of a plurality of wires. The use of the embodiments of the present invention allow a single disconnection to be made at the power supply when a power supply is replaced. This significantly simplifies the process of replacing a personal computer's power supply.

If it is desirable to use an external power supply, the first plug may be mounted in the back panel of the computer. At the back of most personal computers, slots are provided which allow the mounting of additional devices and interfaces. In one embodiment of the present invention, a bracket placed on the first plug would allow the first plug to be mounted in one of these slots with case. An additional cable could then be used to connect this first plug to an external power supply.

An embodiment of the present invention that would allow the use of an external power supply would greatly enhance the ability of technicians in the industry to keep a personal computer operating. Frequently, power supplies are sized and dimensioned to fit within a particular space within a computer case. This develops a situation in which the power supply is somewhat proprietary to individual brand name computers because the power supply must fit within the particular space of a brand name computer. It is very difficult for a repair technician to have on-hand all the various sizes and shapes of power supplies. The embodiment of the present invention which enables the power cable to connect to an external power supply would allow a technician to substitute a generic external power supply for the proprietary internal power supply until an appropriate power supply can be acquired. Even if the original power cable for a given computer does not disconnect from the proprietary power supply, an embodiment of the present invention would allow the substitution of the embodiment into the computer and allow the use of an external power supply. While this may require additional time to change these power connections, this is still preferable to not having the use of the personal computer for the amount of time that it takes to acquire the correct replacement power supply.

### BRIEF DESCRIPTION OF THE DRAWINGS

Additional utility and features of the invention will become more fully apparent to those skilled in the art by reference to the following drawings, which illustrate the primary features of the preferred embodiment.

FIG. 1 shows a first embodiment of the present invention.

FIG. 2 shows an embodiment of the present invention located within a computer.

FIG. 3 shows an additional embodiment of the present invention located within a computer using an external power supply.

FIG. 4 shows an additional embodiment of the present invention having a bracket on a plug.

FIG. 5 shows an additional embodiment of the present invention.

FIG. 6 shows an additional embodiment of the present invention located within a computer.

FIG. 7 shows an additional embodiment of the present invention located within a computer using an external power supply.

FIG. 8 shows an additional embodiment of the present invention having a bracket on a plug.

### DETAILED DESCRIPTION OF PREFERRED EMBODIMENTS

The detailed description below is for embodiments intended to illustrate and explain the current invention. It is to be understood that a variety of other arrangements are also possible without departing from the spirit and scope of the invention. Where appropriate, the same numbering will be used when discussing different embodiments.

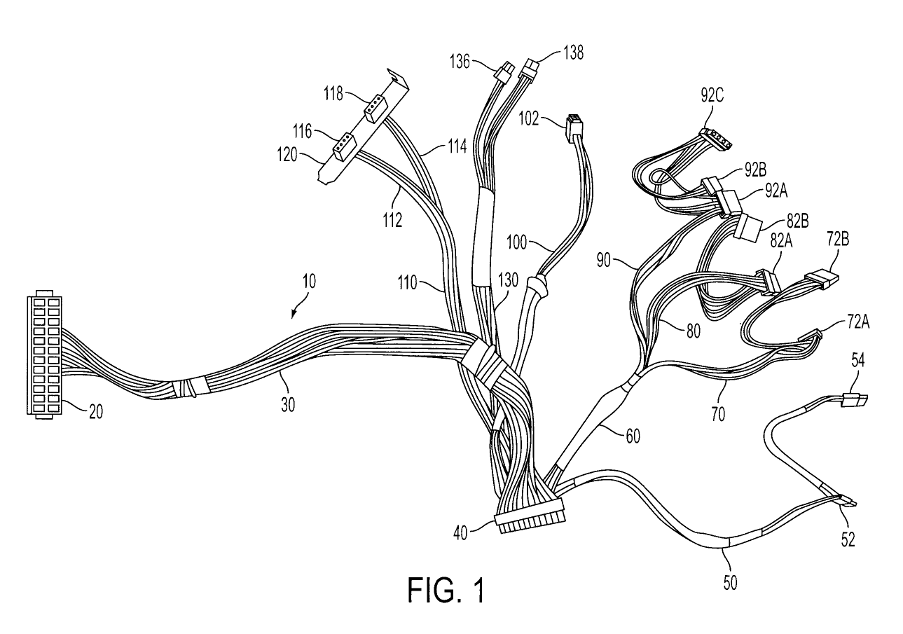

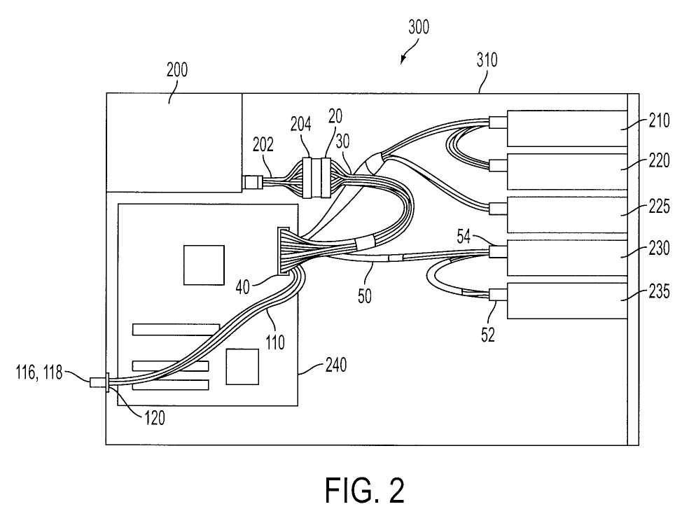

FIG. 1 shows one embodiment of the computer cable 10 of the present invention. FIG. 2 shows one embodiment of the computer cable 10 of the present invention installed within a computer 300. The embodiment of FIG. 1 has a first plug 20 shaped and configured to mate with a receptacle on a power supply. The wires extending from first plug 20 form a main cable 30 which has on its other end a second plug 40. Second plug 40 is shaped and configured to match a receptacle on a mother board in a computer. FIG. 2 shows an embodiment of the present invention installed within a computer 300, and it can be seen that plug 20 of the embodiment 10 is connected to power supply 200, while plug 40 is connected to mother board 240.

Returning to FIG. 1, secondary cables 50, 60, 100, 110 and 130 also terminate at one end in plug 40 and receive power from cable 30. Secondary cable 50 has 2 plugs on it wired in parallel, which are shaped and configured to connect to electrical devices in the computer. Plug 54 is located at the extreme terminal end of secondary cable 50 while plug 52 is located intermediate of plug 54 and plug 40. In FIG. 2, it can be seen that secondary cable 50 extends from plug 40 up to internal electric devices, or drives, 220 and 230, where plugs 52 and 54 connect to provide power to those devices. Plugs 52 and 54 might be serial ATA power cable type plugs, for example, but could be any type of plug intended to fit into an electronic device requiring power.

Secondary cable 60 also attaches to plug 40 but splits out into tertiary cables 70, 80 and 90. Each of the tertiary cables 70, 80 and 90 have upon them plugs shaped and configured to mate with receptacles on electrical devices. Tertiary cables 70 and 80 are somewhat similar to secondary cable 50 in that they each have 2 plugs wired in parallel with one plug at an extreme terminal and with one plug at an intermediate location. Plugs 72A and 72B on tertiary cable 70 and plugs 82A and 82B on tertiary cable 80 might be IDE power cable type plugs, for example, but could be any type of plug intended to fit into an electronic device requiring power, including the serial ATA power cable type plugs mentioned above. Tertiary cable 90 which splits out from secondary cable 60 has 3 plugs on it, one at an extreme end and two at intermediate locations along the length of tertiary cable 90. These plugs, 92A, 92B, and 92C can be any type of plug needed, including the types already mentioned above. Tertiary cable 100 extends from second plug 40 and has a single plug 102 at its terminal end. Plug 102 might be a CPU power cable type plug, for example, but could be any type of plug intended to fit into an electronic device requiring power.

Secondary cable 110 also splits into tertiary cables 112 and 114 which terminate at their extremities in plugs 116 and 118, respectively. Plugs 116 and 118 are mounted in bracket 120 to facilitate the mounting of plugs 116 and 118 at the surface of a computer. Plugs 116 and 118 may then be used to supply power to external devices. Referring to FIG. 2, secondary cable 110 may be seen extending back in computer 300 to bracket 120 mounted at the surface of computer 300. Plugs 116 and 118 are aligned in the view presented in FIG. 2.

Referring back to FIG. 1, secondary cable 130 is also connected at one of its ends to a second plug 40. At its other end, secondary cable 130 splits into two cables, each of which terminates in plugs 136 and 138. Secondary cable 130 and its terminating plugs 136 and 138 might be configured to serve as a PCI Express cable, for example, but could also be configured to serve other power needs as deemed necessary. Other configurations have been mentioned above, but configurations not specifically mentioned could also be used.

The specific number and arrangement of secondary cables 50, 60, 100, 110, and 130 along with the specific number and arrangement of tertiary cables 70, 80 and 90 and all of the plugs shown in FIG. 1 are by way of example only. The specific arrangement of cables may be varied depending upon the configuration of the computer into which the embodiment will be installed. Also, FIG. 2 shows an embodiment that varies somewhat from that of FIG. 1 in order to avoid excessive clutter within the computer case 310 of FIG. 2. If a plurality of plugs are needed in a specific area of a computer, the particular embodiment for that application might use a secondary cable, such as secondary cable 60 which would provide several tertiary cables with plugs to provide power to the several devices in the specific area of the computer. Also, the ability to have several secondary cables such as 50, 60 and 100 along with tertiary cables 70, 80 and 90 allows many different types of plugs to be available upon the power cable 10 to service an extremely wide array of electrical devices such as 210, 220 and 230 with the same power cable 10.

Referring now again to FIG. 2, it is apparent how an embodiment of the present invention would simplify the exchange of a new power supply 200 for a failed power supply 200. To remove power supply 200 once access is gained to the inside of computer 300, plug 20 of cable 10 is disconnected from power supply 200. A new power supply 200 is switched in for the failed power supply 200 and plug 20 is then connected to the new power supply. This requires the disconnection of a single plug, as opposed to disconnecting power plugs from several electronic devices.

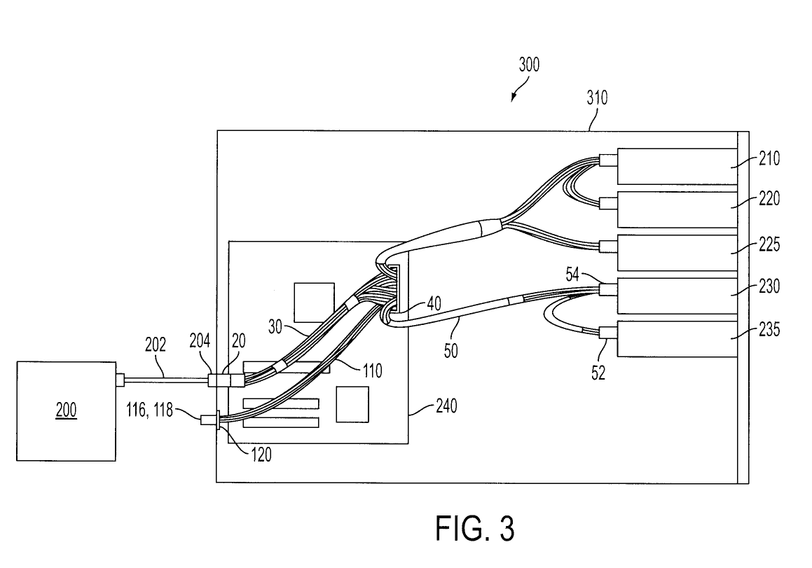

FIG. 3 shows an embodiment of the present invention installed within a computer and connected to an external power supply 200. The computer 300 may be configured this way initially, or it may be configured in this way during a repair. Referring to FIG. 2 and FIG. 3, for example, if the computer 300 of FIG. 2 had a power supply failure, but the appropriately sized power supply 200 was not available, computer 300 could be temporarily configured as in FIG. 3. FIG. 3 shows an external power supply 200 connected by cable 202 and plug 204 to the rear of computer 300. Plug 20 of power cable 10 is moved from the location of the internal power supply down to the exit at the rear of the computer case 310, and it is plug 20 to which plug 204 attaches. When an appropriately sized and shaped power supply is acquired, the computer may be reconfigured from that of FIG. 3 to that of FIG. 2 with power supply 200 located internally of computer case 310 and plug 20 connected as shown in FIG. 2.

Power supplies, generally, can be a source for a considerable amount of heat. Accordingly, for some computer applications, it may be desirable to remove the power supply from the inside of the computer case. In those situations, the configuration of FIG. 3 could employ an embodiment of the present invention to allow a single plug 20 to interface with the external power supply.

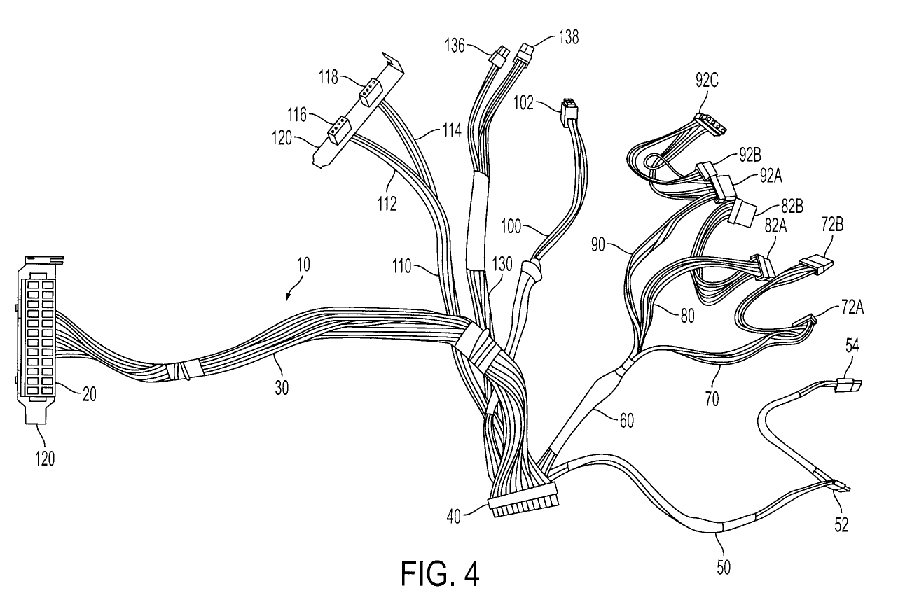

FIG. 4 shows an additional embodiment of the present invention. Plug 20 has a mounting bracket 120 which allows plug 20 to be easily and securely mounted into the back of computer case 310 such as is shown in FIG. 3. Mounting bracket 120 can be configured for the particular computer case and may vary substantially depending on the preferences in the particular application.

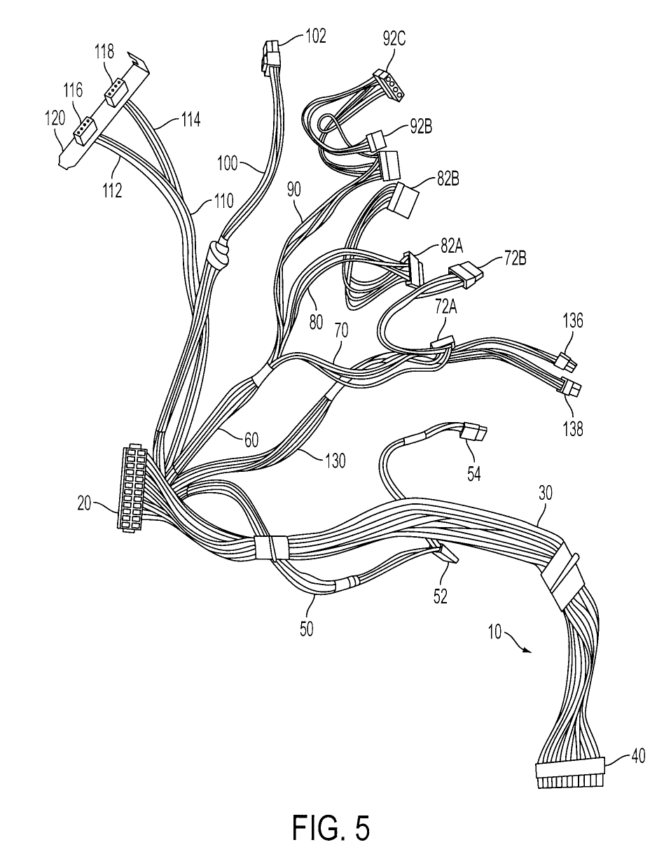

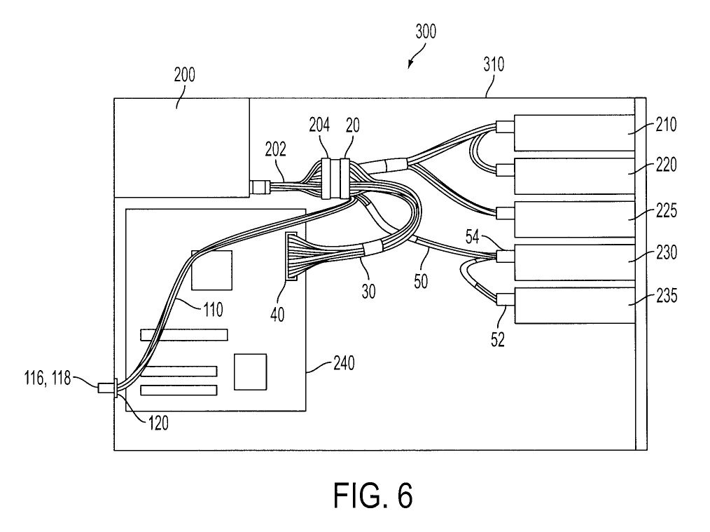

FIG. 5 shows one embodiment of the computer cable 10 of the present invention. FIG. 6 shows one embodiment of the computer cable 10 of the present invention installed within a computer 300. The embodiment of FIG. 5 has a first plug 20 shaped and configured to mate with a receptacle on a power supply. The wires extending from first plug 20 form a main cable 30 which has on its other end, a second plug 40. Second plug 40 is shaped and configured to match a receptacle on a mother board in a computer. FIG. 6 shows an embodiment of present invention installed within a computer 300, and it can be seen that plug 20 of the embodiment 10 is connected to power supply 200, while plug 40 is connected to mother board 240.

Returning to FIG. 5, the wires of secondary cables 50, 60, 100, 110 and 130 also terminate at one end in plug 20 and receive power through plug 20. Secondary cable 50 has 2 plugs on it wired in parallel, which are shaped and configured to connect to electrical devices in the computer. Plug 54 is located at the extreme terminal end of secondary cable 50 while plug 52 is located intermediate of plug 54 and plug 20. In FIG. 6, it can be seen that secondary cable 50 extends from plug 20 up to internal electric devices, or drives, 220 and 230, where plugs 52 and 54 connect to provide power to those devices. Plugs 52 and 54 might be serial ATA power cable type plugs, for example, but could be any type of plug intended to fit into an electronic device requiring power.

Secondary cable 60 also attaches to plug 20 but also splits out into tertiary cables 70, 80 and 90. Each of the tertiary cables 70, 80 and 90 have upon them plugs shaped and configured to mate with receptacles on electrical devices. Tertiary cables 70 and 80 are somewhat similar to secondary cable 50 in that they each have 2 plugs wired in parallel with one plug at an extreme terminal and with one plug at an intermediate location. Plugs 72A and 72B on tertiary cable 70 and plugs 82A and 82B on tertiary cable 80 might be IDE power cable type plugs, for example, but could be any type of plug intended to fit into an electronic device requiring power, including the serial ATA power cable type plugs mentioned above. Tertiary cable 90 which splits out from secondary cable 60 has 3 plugs on it, one at an extreme end and two at intermediate locations along the length of tertiary cable 90. These plugs, 92A, 92B, and 92C can be any type of plug needed, including the types already mentioned above. Tertiary cable 100 extends from first plug 20 and has a single plug 102 at its terminal end. Plug 102 might be a CPU power cable type plug, for example, but could be any type of plug intended to fit into an electronic device requiring power.

Secondary cable 110 also splits into tertiary cables 112 and 114 which terminate at their extremities in plugs 116 and 118, respectively. Plugs 116 and 118 are mounted in bracket 120 to facilitate the mounting of plugs 116 and 118 at the surface of a computer. Plugs 116 and 118 may then be used to supply power to external devices. Referring to FIG. 6, secondary cable 110 may be seen extending back in computer 300 to bracket 120 mounted at the surface of computer 300. Plugs 116 and 118 are aligned in the view presented in FIG. 6.

Referring back to FIG. 5, secondary cable 130 is also connected at one of its ends to first plug 20. At its other end, secondary cable 130 splits into two cables, each of which terminates in plugs 136 and 138. Secondary cable 130 and its terminating plugs 136 and 138 might be configured to serve as a PCI Express cable, for example, but could also be configured to serve other power needs as deemed necessary. Other configurations have been mentioned above, but configurations not specifically mentioned could also be used.

The specific number and arrangement of secondary cables 50, 60, 100, 110, and 130 along with the specific number and arrangement of tertiary cables 70, 80 and 90 and all of the plugs shown in FIG. 5 are by way of example only. The specific arrangement of cables may be varied depending upon the configuration of the computer into which the embodiment will be installed. Also, FIG. 6 shows an embodiment that varies somewhat from that of FIG. 5 in order to avoid excessive clutter within the computer case 310 of FIG. 6. If a plurality of plugs are needed in a specific area of a computer, the particular embodiment for that application might use a secondary cable, such as secondary cable 60 which would provide several tertiary cables with plugs to provide power to the several devices in the specific area of the computer. Also, the ability to have several secondary cables such as 50, 60 and 100 along with tertiary cables 70, 80 and 90 allows many different types of plugs to be available upon the power cable 10 to service an extremely wide array of electrical devices such as 210, 220 and 230 with the same power cable 10.

Referring now again to FIG. 6, it is apparent how an embodiment of the present invention would simplify the exchange of a new power supply 200 for a failed power supply 200. To remove power supply 200 once access is gained to the inside of computer 300, plug 20 of cable 10 is disconnected from power supply 200. A new power supply 200 is switched in for the failed power supply 200 and plug 20 is then connected to the new power supply. This requires the disconnection of a single plug, as opposed to disconnecting power plugs from several electronic devices.

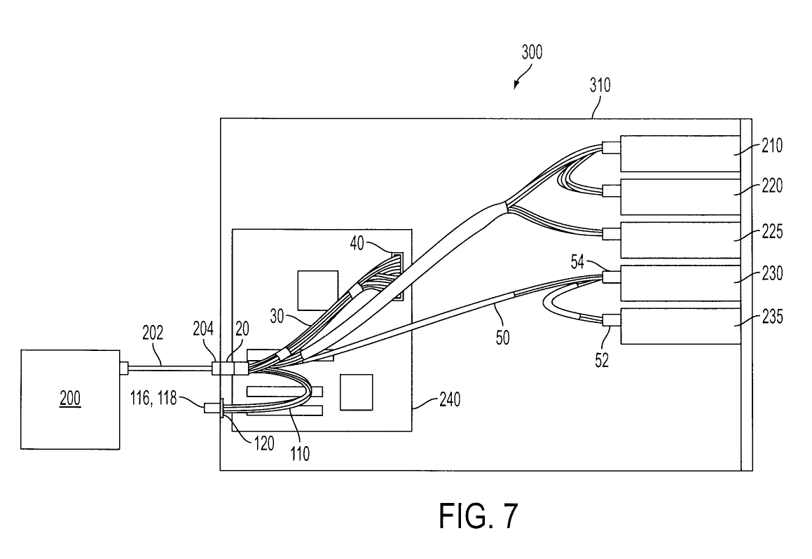

FIG. 7 shows an embodiment of the present invention installed within a computer and connected to an external power supply 200. The computer 300 may be configured this way initially, or it may be configured in this way during a repair. Referring to FIG. 6 and FIG. 7, for example, if the computer 300 of FIG. 6 had a power supply failure, but the appropriately sized power supply 200 was not available, computer 300 could be temporarily configured as in FIG. 7. FIG. 7 shows an external power supply 200 connected by cable 202 and plug 204 to the rear of computer 300. Plug 20 of power cable 10 is moved from the location of the internal power supply down to the exit at the rear of the computer case 310, and it is plug 20 to which plug 204 attaches. When an appropriately sized and shaped power supply is acquired, the computer may be reconfigured from that of FIG. 7 to that of FIG. 6 with power supply 200 located internally of computer case 310 and plug 20 connected as shown in FIG. 6.

Power supplies, generally, can be a source for a considerable amount of heat. Accordingly, for some computer applications it may be desirable to remove the power supply from the inside of the computer case. In those situations, the configuration of FIG. 7 could employ an embodiment of the present invention to allow a single plug 20 to interface with the external power supply.

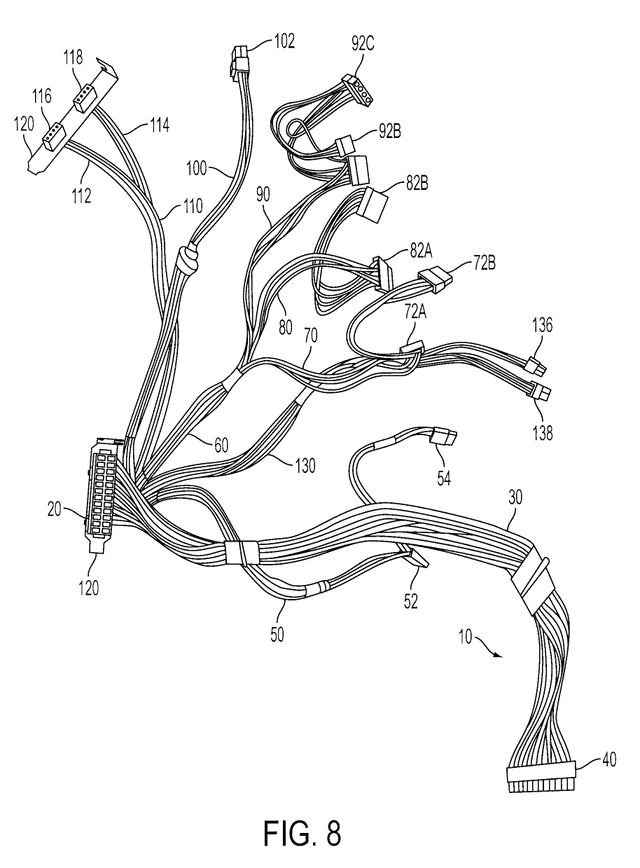

FIG. 8 shows an additional embodiment of the present invention. Plug 20 has a mounting bracket 120 which allows plug 20 to be easily and securely mounted into the back of computer case 310 such as is shown in FIG. 7. Mounting bracket 120 can be configured for the particular computer case and may vary substantially depending on the preferences in the particular application.

Having described embodiments of the present invention in detail, it should be appreciated that a wide variety of embodiments are possible. The number of secondary cables such as secondary cables 50, 60, 100, 110, and 130 can be varied, as well as the number of tertiary cables such as 70, 80 and 90 which may split out from those secondary cables. Also plugs 52, 54, 72A, 72B, 82A, 82B, 92A, 92B, 92C, 100, and 130 may vary substantially in their configuration in order to provide a wide range of connections. The wiring among the plugs may also vary between being electrically in parallel, and electrically in series. This latter variation, as with the others, depends on the specifications of the electronic devices within the computer. Also, it should be appreciated that additional plugs may be included to supply power to external devices at different locations on the surface of computer case 310.

I claim:

1. A power cable for computers, comprising:
a main cable having a first end and a second end, said main cable being comprised of a plurality of wires,
a first plug configured to connect to a computer power supply, said first end of said main cable terminating in said first plug;
a second plug configured to connect to a socket in a computer motherboard, said second end of said main cable terminating in said second plug;
at least one secondary cable having a first end and a second end, said at least one secondary cable being comprised of a plurality of wires, said first end of said at least one secondary cable terminating in either said first plug or said second plug, and said second end of said at least one secondary cable terminating in a device plug configured to connect to an electrical device within said computer.

2. The power cable for computers of claim 1, wherein;
said at least one secondary cable has at least one device plug located intermediate of said first end of said at least one secondary cable and said second end of said at least one secondary cable.

3. The power cable of claim 1, wherein;
said plurality of wires of said at least one secondary cable split into at least two tertiary cables, each said tertiary cable having at least one device plug configured to connect to an electrical device to deliver power.

4. The power cable of claim 1, wherein;
said first plug has a mounting bracket to facilitate the mounting of
said first plug at the surface of a computer case.

5. The power cable of claim 1, wherein;
at least one of said device plugs is mounted in a bracket to facilitate the mounting
of said at least one of said device plugs at the surface of a computer case.

6. A computer comprising;
a case;
a mother board mounted within said case, said motherboard having a connector configured to receive a plug from a power cable;
an internal power supply mounted within said case, said internal power supply having a connector configured to receive a plug from a power cable;
at least one electrical device mounted in said case, said at least one electrical device having a connector configured to receive a device plug from a power cable; and,
the power cable for computers of claim 1, wherein;
said first plug of said power cable for computers is connected to said connector of said internal power supply;
said second plug of said power cable for computers is connected to said connector of said motherboard; and,
said at least one device plug is connected to a connector for an electrical electrical device.

7. A computer comprising;
a case;
a mother board mounted within said case, said motherboard having a connector configured to receive a plug from a power cable;
an external power supply external to said case, said external power supply having a connector configured to receive a plug from a power cable;
at least one electrical device mounted in said case, said at least one electrical device having a connector configured to receive a device plug from a power cable; and,
the power cable for computers of claim 4, wherein;
said first plug of said power cable for computers is mounted at the surface of said computer case and connected to said connector of said external power supply;
said second plug of said power cable for computers is connected to said connector of said motherboard; and,
said at least one device plug is connected to a connector for an electrical device.

8. The power cable for computers of claim 1, wherein;
said first end of at least one of said at least one secondary cables terminates in said first plug, and
said first end of at least one of said at least one secondary cables terminates in said second plug.

9. A computer comprising;
a case;
a mother board mounted within said case, said motherboard having a connector configured to receive a plug from a power cable;
an internal power supply mounted within said case, said internal power supply having a connector configured to receive a plug from a power cable;
at least one electrical device mounted in said case, said at least one electrical device having a connector configured to receive a device plug from a power cable; and,
the power cable for computers of claim 8, wherein;
said first plug of said power cable for computers is connected to said connector of said internal power supply;
said second plug of said power cable for computers is connected to said connector of said motherboard; and,
at least one of said at least one device plugs is connected to a connector for an electrical device.

10. The power cable for computers of claim 1, wherein;
said first end of said at least one secondary cable terminates in said first plug.

11. The power cable for computers of claim 1, wherein;
said first end of said at least one secondary cable terminates in said second plug.

12. A power cable for computers, comprising:
a main cable having a first end and a second end, said main cable being comprised of a plurality of wires,
a first plug configured to connect to a computer power supply, said first end of said main cable terminating in said first plug;
a second plug configured to connect to a socket in a computer motherboard, said second end of said main cable terminating in said second plug;
at least one secondary cable having a first end and a second end, said at least one secondary cable being comprised of a plurality of wires, said first end of said at least one secondary cable terminating in said second plug, and said second end of said at least one secondary cable terminating in a device plug configured to connect to an electrical device to deliver power.

13. A method of repairing a computer with a failed power supply by using a repair power cable, wherein;
said repair power cable comprises;
a main cable having a first end and a second end, said main cable being comprised of a plurality of wires,
a first plug configured to connect to a computer power supply, said first end of said main cable terminating in said first plug;
a second plug configured to connect to a socket in a computer motherboard, said second end of said main cable terminating in said second plug;
at least one secondary cable having a first end and a second end, said at least one secondary cable being comprised of a plurality of wires, said first end of said at least one secondary cable terminating in either said first plug or said second plug, and said second end of said at least one secondary cable terminating in a device plug configured to connect to an electrical device within said computer; and,
wherein said computer comprises;
a case;
a mother board mounted within said case, said motherboard having a connector configured to receive a plug from a power supply;
at least one electrical device mounted in said case, said at least one electrical device having a connector configured to receive a device plug from a power cable;
a failed internal power supply mounted within said case, said failed internal power supply having a power supply power cable, said power supply power cable having a plug connected to said motherboard, and said failed power supply having at least one power supply secondary cable, said at least one power supply secondary cable having at least one device plug connected to an electrical device within said computer;
said method comprising;
disconnecting said power supply power cable from said motherboard;
disconnecting all said at least one power supply secondary cables from all said electrical devices within said computer;
removing said failed power supply;
installing said repair power cable by connecting said second plug of said repair power cable to said motherboard, connecting all said electrical devices to an at least one device plug of said repair power cable, and mounting said first plug of said repair power cable at the surface of said case of said computer; and,
connecting an external power supply to said first plug of said repair power cable.
